(19) United States
(12) Patent Application Publication
(10) Pub. No.: US 2022/0068213 A1
(43) Pub. Date: Mar. 3, 2022

(54) SCANNING DRIVE CIRCUIT AND DISPLAY PANEL

(71) Applicant: SHENZHEN ROYOLE TECHNOLOGIES CO., LTD., Shenzhen (CN)

(72) Inventors: Weiyao WEI, Shenzhen (CN); Yao YAN, Shenzhen (CN)

(21) Appl. No.: 17/412,378

(22) Filed: Aug. 26, 2021

(30) Foreign Application Priority Data
Aug. 26, 2020 (CN) 202010874306.5

(51) Int. Cl. G09G 3/3266

(52) U.S. Cl. CPC G09G 3/3266

(57) ABSTRACT

The present invention provides a scanning drive circuit (10), including a pull-down control module (100), a pull-down output module (200), a pull-up control module (300) and an output end (Eout), where a first node (PD) is arranged between the pull-down control module (100) and the pull-down output module (200), the pull-down control module (100) and the pull-down output module (200) are respectively electrically connected to the first node (PD), and the output end (Eout) is configured to be connected to a light-emitting unit. Whether in a data write-in stage or a light-emitting stage, the pull-down control module (100) controls a potential of the first node (PD) which controls an input result input to the output end (Eout) from the pull-down output module (200). So, the light-emitting unit can be controlled to emit light in time, thereby improving a light-emitting display effect. The present invention further provides a display panel.

### TECHNICAL FIELD

The present invention relates to the field of display technologies, and in particular, to a scanning drive circuit and a display panel.

### BACKGROUND

As high-definition display screens develop, people are pursuing larger screens, higher resolutions and more exciting visual effects. Developing display technologies for a wide viewing angle, a high color gamut and a high pixel density has become an industry trend. Due to the advantages such as high contrast, a wide viewing angle, high saturation, and low energy consumption, an organic light-emitting diode (OLED) screen has been pushed to the development forefront of the display market. Pixel drive method of an OLED display drive technology is a current-type drive technology, which requires a gate on array (GOA) to supply scanning signals. An existing scanning drive circuit usually includes a pull-up control module, a pull-up output module, a pull-down control module and a pull-down output module. In a data write-in stage, the pull-down control module is configured to control the pull-down output module to output a low level; and in a light-emitting stage, the pull-up control module is configured to control the pull-up output module to output a high level and control, via the high level, a light-emitting unit to emit light. At present, the pull-up control module is connected to the pull-down control module in most cases. When switching is performed between the pull-up control module and the pull-down control module, a device structure of the pull-down control module pulls down a level of a control signal of the pull-up control module. As a result, time for the pull-down output module to output a high level under control by the control signal is prolonged in the light-emitting stage, and display effect of the light-emitting unit is affected.

### SUMMARY

In view of the problems, the present invention provides a scanning drive circuit that can reduce impact caused by a delay in light-emitting display of a light-emitting unit. A specific technical solution is as follows.

Disclosed is a scanning drive circuit, including a pull-down control module, a pull-down output module, a pull-up control module and an output end, where the pull-down control module is connected to the pull-up control module, a first node is arranged between the pull-down control module and the pull-down output module, the pull-down control module and the pull-down output module are electrically connected to the first node, respectively, the output end is configured to be connected to a light-emitting unit, one end of the pull-down output module is connected to a first signal end, and the other end thereof is connected to the output end; and the scanning drive circuit has a data write-in stage and a light-emitting stage, and the light-emitting stage is after the data write-in stage;

in the data write-in stage, the first signal end inputs a low level, the pull-down control module controls the first node to be at a first level, and the first level of the first node controls the pull-down output module to transmit the low level of the first signal end to the output end; and

in the light-emitting stage, the first signal end inputs a high level, the pull-down control module controls the first node to be at the first level, the first level of the first node controls the pull-down output module to transmit the high level of the first signal end to the output end, and the high level output from the output end is used to control the light-emitting unit to emit light.

The present invention further provides a display panel, including a light-emitting unit and the scanning drive circuit described above, where the scanning drive circuit is configured to control the light-emitting unit to emit light.

The present invention further provides an electronic apparatus, including the display panel described above.

The present invention has the following beneficial effects: In the scanning drive circuit provided in the present application, a pull-down control module controls a first node to be at a first level in a data write-in stage and a light-emitting stage, and the first level of the first node controls a pull-down output module to transmit a high level of a first signal end to an output end. That is, when switching is performed between the data write-in stage and the light-emitting stage in the present application, a device structure of the pull-down control module during switching can be prevented from pulling a level of a control signal of a pull-up control module and affecting a light-emitting effect. In both the data write-in stage and the light-emitting stage, the level is controlled by the pull-down control module, so that a signal output from the output end is timely, and the high level output from the output end can control a light-emitting unit to emit light in time, thereby improving a light-emitting display effect.

### BRIEF DESCRIPTION OF DRAWINGS

FIG. 1 is a schematic structural diagram illustrating a scanning drive circuit according to a first embodiment of the present invention;

FIG. 2 is a schematic structural diagram illustrating a scanning drive circuit according to a second embodiment of the present invention;

FIG. 3 is an operation time sequence diagram illustrating the scanning drive circuit according to the second embodiment of the present invention;

FIG. 4 is a schematic structural diagram illustrating a scanning drive circuit according to a first comparative embodiment of the present invention;

FIG. 5 is an operation time sequence diagram illustrating the scanning drive circuit according to the first comparative embodiment of the present invention;

FIG. 6 is a schematic structural diagram illustrating a scanning drive circuit according to a third embodiment of the present invention;

FIG. 7 is an operation time sequence diagram illustrating the scanning drive circuit according to the third embodiment of the present invention;

FIG. 8 is a schematic structural diagram illustrating a scanning drive circuit according to a second comparative embodiment of the present invention;

FIG. 9 is an operation time sequence diagram illustrating the scanning drive circuit according to the second comparative embodiment of the present invention;

FIG. 10 is a schematic structural diagram illustrating a scanning drive circuit according to a fourth embodiment of the present invention;

FIG. 11 is an operation time sequence diagram illustrating the scanning drive circuit according to the fourth embodiment of the present invention;

FIG. 12 is a schematic structural diagram illustrating a scanning drive circuit according to a fourth embodiment of the present invention;

FIG. 13 is a schematic structural diagram illustrating a display panel according to an embodiment of the present invention; and

FIG. 14 is a schematic structural diagram of an electronic apparatus according to an embodiment of the present invention.

### DESCRIPTION OF EMBODIMENTS

The descriptions below are preferred implementations of the present invention. It should be noted that for a person of ordinary skill in the art, several improvements and polishing may also be made without departing from the principle of the present invention, and the improvements and polishing should be regarded as falling within the protection scope of the present invention.

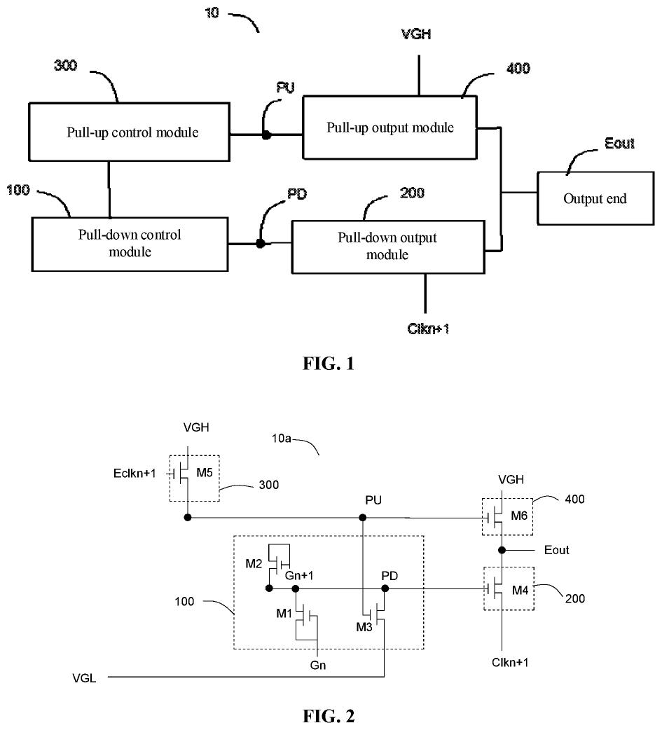

Referring to FIG. 1, a first embodiment of the present invention provides a scanning drive circuit 10. The scanning drive circuit 10 includes a pull-down control module 100, a pull-down output module 200, a pull-up control module 300 and an output end Eout. The pull-down control module 100 is connected to the pull-up control module 300, a first node PD is arranged between the pull-down control module 100 and the pull-down output module 200, both the pull-down control module 100 and the pull-down output module 200 are electrically connected to the first node PD, the output end Eout is configured to be connected to a light-emitting unit (not shown), one end of the pull-down output module 200 is connected to a first signal end Clkn+1, and the other end thereof is connected to the output end Eout; and the scanning drive circuit 10 has a data write-in stage T3 and a light-emitting stage T4, and the light-emitting stage T4 is after the data write-in stage T3. The pull-down control module 100 controls a level signal of the first node PD, and the level signal of the first node PD is used to control the pull-down output module 200 to input a signal of the first signal end Clkn+1 to the output end Eout.

In the data write-in stage T3, the first signal end Clkn+1 inputs a low level, the pull-down control module 100 controls the first node PD to be at a first level, and the first level of the first node PD controls the pull-down output module 200 to transmit the low level of the first signal end Clkn+1 to the output end Eout. The low level output from the output end Eout controls the light-emitting unit to receive light-emitting data.

In the light-emitting stage T4, the first signal end Clkn+1 inputs a high level, the pull-down control module 100 controls the first node PD to be at the first level, the first level of the first node PD controls the pull-down output module 200 to transmit the high level of the first signal end Clkn+1 to the output end Eout, and the high level output from the output end Eout is used to control the light-emitting unit to emit light. The light-emitting unit may be an organic electroluminescence display unit or an inorganic light-emitting display unit.

In this embodiment, the pull-down control module 100 is connected to the pull-up control module 300. In the prior art, in the data write-in stage T3, the pull-down control module 100 is configured to control the pull-down output module 200 to output a low level; and in the light-emitting stage T4, the pull-up control module 300 is configured to control a pull-up output module 400 to output a high level and control, via the high level, the light-emitting unit to emit light. Because the pull-up control module 300 is connected to the pull-down control module 100, when switching is performed between the pull-up control module 300 and the pull-down control module 100, a device structure of the pull-down control module 100 pulls a signal of the pull-up control module 300 in the light-emitting stage T4. For example, a thin film transistor in the pull-down control module 100 pulls down a level of a control signal of pull-up output module 400 controlled by the pull-up control module 300. As a result, the control signal cannot effectively control the pull-up output module 400 to output a high level in time in the light-emitting stage T4, which leads to the time for the pull-up output module 400 to output the high level being prolonged and a display effect of the light-emitting unit being affected.

In the scanning drive circuit 10 provided in the present application, the pull-down control module 100 controls the first node PD to be at the first level in both the data write-in stage T3 and the light-emitting stage T4, and the first level of the first node PD controls the pull-down output module 200 to transmit the high level of the first signal end Clkn+1 to the output end Eout. In other words, when switching is performed between the data write-in stage T3 and the light-emitting stage T4 in the present application, a device structure of the pull-down control module 100 can be prevented from pulling down the level of the control signal of the pull-up control module 300 and further affecting a display effect of the light-emitting unit. The data write-in stage T3 and the light-emitting stage T4 alike in the present application are controlled by the pull-down control module 100, so the signal from the output end Eout is timely and the high level output from the output end Eout can control the light-emitting unit to emit light in time, thereby improving a light-emitting display effect.

In a further embodiment, the scanning drive circuit 10 further has an initialization stage T1 and a compensation stage T2. The compensation stage T2 is after the initialization stage T1, and it is between the initialization stage T1 and the data write-in stage T3.

In the initialization stage T1, the first signal end Clkn+1 inputs a low level; then the pull-down control module 100 controls the first node PD to be at the first level; the first level of the first node PD further controls the pull-down output module 200 to transmit the low level to the output end Eout. Consequently, the output end Eout inputs the low level to the light-emitting unit to complete initialization of the light-emitting unit and clear light-emitting information of the previous stage.

In the compensation stage T2, the first signal end Clkn+1 inputs a high level; then the pull-down control module 100 controls the first node PD to be at a first level; the first level of the first node PD further controls the pull-down output module 200 to transmit the high level to the output end Eout. Therefore, the output end Eout inputs the high level to the light-emitting unit so as to complete data compensation for the light-emitting unit and prevent uneven and unstable brightness caused by drifting of a threshold voltage and a power voltage of the light-emitting unit after the luminescence time of the light-emitting unit increases. That is to say, in all the stages from the initialization stage T1, the compensation stage T2, the data write-in stage T3 to the light-emitting stage T4, the pull-down output module 200 is controlled by the pull-down control module 100 controls to input an output result to the output end Eout. Such practice can further reduce the impact of signal interference caused by switching of the control modules in the respective stages and improve control accuracy of the scanning drive circuit 10.

In a further embodiment, the scanning drive circuit 10 further includes the pull-up output module 400. Between the pull-up control module 300 and the pull-up output module 400 is arranged a second node PU, which is electrically connected to the pull-up control module 300 and the pull-up output module 400 respectively. The second end of the pull-up output module 400 is connected to a second signal end VGH and the third one is connected to the output end Eout; and the scanning drive circuit 10 further has a light-emitting holding stage T5, which follows the light-emitting stage T4.

In the light-emitting holding stage T5, the second signal end VGH inputs a high level, the pull-up control module 300 controls the second node PU to be at a first level, then the first level of the second node PU controls the pull-up output module 400 to transmit the high level to the output end Eout, and the high level from the output end Eout controls the light-emitting unit to emit light.

In the present application, in the light-emitting stage T4, the pull-down output module 200 transmits the high level of the first signal end Clkn+1 to the output end Eout, and the high level from the output end Eout is used to control the light-emitting unit to emit light; in the light-emitting holding stage T5, the pull-up output module 400 transmits the high level to the output end Eout, and the high level from the output end Eout controls the light-emitting unit to emit light. That is, in the light-emitting stage T4 and the light-emitting holding stage T5, levels input to the output end Eout are high levels; the high level of the light-emitting holding stage T5 is switched from the high level of the light-emitting stage T4 without the mutual pulling between a high level and a low level. As such, the output stability of the high levels of the output end Eout will be not adversely affected, thereby improving display stability of the light-emitting unit.

Still referring to FIG. 2, a second embodiment of this invention provides a scanning drive circuit 10a. In the scanning drive circuit 10a, the pull-down control module 100 includes a first thin film transistor M1, a second thin film transistor M2 and a third thin film transistor M3.

A first electrode of the first thin film transistor M1 is connected to the first node PD; a second electrode and a gate of it are connected to a third signal end Gn; the first electrode and the second electrode of it correspond to its a source and a drain. A gate and a first electrode of the second thin film transistor M2 are connected to a fourth signal end Gn+1; a second electrode of it is connected to the first node PD. A gate of the third thin film transistor M3 is connected to the pull-up control module 300; a first electrode of it is connected to a fifth signal end VGL, and its second electrode is connected to the first node PD.

In the data write-in stage T3, the third signal end Gn inputs a first level, under the control of which the first thin film transistor M1 is turned on; the first level is input to the first node PD through the first thin film transistor Ml, so the first node PD is at the first level, under the control of which the pull-down output module 200 transmits the low level of the first signal end Clkn+1 to the output end Eout. The fourth signal end Gn+1 inputs a second level, under the control of which the second thin film transistor M2 is turned off.

In the light-emitting stage T4, the third signal end Gn inputs a second level, under the control of which the first thin film transistor M1 is turned off. The fourth signal end Gn+1 inputs a first level, under the control of which the second thin film transistor M2 is turned on; the first level is input to the first node PD through the second thin film transistor M2, so the first node PD is at the first level, under the control of which the pull-down output module 200 transmits the high level of the first signal end Clkn+1 to the output end Eout and then the high level from the output end Eout is used to control the light-emitting unit to emit light.

In a further embodiment, the pull-down output module 200 includes a fourth thin film transistor M4, of which a gate is connected to the first node PD, a first electrode is connected to the first signal end Clkn+1, and a second electrode is connected to the output end Eout.

In the data write-in stage T3, the fourth thin film transistor M4 is turned on under the control of the first level of the first node PD, and the low level of the first signal end Clkn+1 is input to the output end through the fourth thin film transistor M4.

In the light-emitting stage T4, the fourth thin film transistor M4 is turned on under the control of the first level of the first node PD, the high level of the first signal end Clkn+1 is input to the output end Eout through the fourth thin film transistor M4, and the high level output from the output end Eout is used to control the light-emitting unit to emit light.

In a further embodiment, the pull-up control module 300 further includes a fifth thin film transistor M5, of which a gate is connected to a sixth signal end Eclkn+1, a first electrode is connected to the second node PU, and a second electrode is connected to the second signal end VGH.

In the light-emitting holding stage T5, the sixth signal end Eclkn+1 inputs a first level. under the control of the first level, the fifth thin film transistor M5 is turned on, then the high level input from the second signal end VGH is input to the second node PU through the fifth thin film transistor M5, and then the high level of the second node PU controls the pull-up output module 400 to transmit the high level of the second signal end VGH to the output end Eout. The high level output from the output end Eout controls the light-emitting unit to emit light.

In a further embodiment, the pull-up output module 400 further includes a sixth thin film transistor M6, of which a gate is connected to the second node PU, a first electrode is connected to the output end Eout, and a second electrode is connected to the second signal end VGH.

In the light-emitting holding stage T5, the second signal end VGH inputs the high level. Under the control of the high level of the second node PU, the sixth thin film transistor M6 is turned on, then the high level of the second signal end VGH is input to the output end Eout through the sixth thin film transistor M6. The high level output from the output end Eout controls the light-emitting unit to emit light.

A working process of the scanning drive circuit 10a of the second embodiment is analyzed below with reference to the second embodiment (shown in FIG. 2) and the time sequence diagram (shown in FIG. 3). In this implementation, all thin film transistors are N-type thin film transistors, which are turned on when a gate voltage is a high level, and are turned off when the gate voltage is a low level. In this implementation, the first level is a high level, and the second level is a low level. A time period of the scanning drive circuit 10 includes the initialization stage Ti, the compensation stage T2, the data write-in stage T3, the light-emitting stage T4 and the light-emitting holding stage T5 that are sequentially adjacent, where the initialization stage T1 of the next time period is adjacent to the light-emitting holding stage T5 of the previous time period. It should be noted that, compared with a signal waveform diagram shown in FIG. 3, in other periods of time, a time period in the signal waveform diagram may shift forward or backward by one or more phases. The working process of this embodiment is specifically as follows:

The initialization stage Ti includes a first initialization sub-stage T11 and a second initialization sub-stage T12 after the first initialization sub-stage T11.

In the first initialization sub-stage T11, the fourth signal end Gn+1 inputs a low level, under the control of which the second thin film transistor M2 is turned off; the sixth signal end Eclkn+1 inputs a low level, under the control of which the fifth thin film transistor M5 is turned off, at the same time, the node PU is at a low level, under the control of which the third thin film transistor M3 and the sixth thin film transistor M6 are turned off; and the third signal end Gn inputs a high level, under the control of which the first thin film transistor M1 is turned on. Then the high level is input to the first node PD through the first thin film transistor M1. Then under the control of the high level of the first node PD, the fourth thin film transistor M4 is turned on; a low level input from the first signal end Clkn+1 is transmitted to the output end Eout through the fourth thin film transistor M4, and the output end Eout outputs the low level to the light-emitting unit to initialize data of the light-emitting unit, so as to eliminate light-emitting display data of the previous stage.

In the second initialization sub-stage T12, the third signal end Gn inputs a low level, under the control of which the first thin film transistor M1 is turned off; the fourth signal end Gn+1 inputs a low level, under the control of which the second thin film transistor M2 is turned off; and the sixth signal end Eclkn+1 inputs a low level, under the control of which the fifth thin film transistor M5 is turned off and the second node PU is at a low level. Under the control of the low level of the second node PU, the third thin film transistor M3 and the sixth thin film transistor M6 are turned off. The first node PD is further held at a high level, because the first node PD is at a high level in the first initialization sub-stage T11 and there is no path for pulling down the high level of the first node PD in the second initialization sub-stage T12 due to the first thin film transistor M1, the second thin film transistor M2 and the third thin film transistor M3 connected to the first node PD all are in a turned-off state. Therefore, in the second initialization sub-stage T12, the first node PD is still held at a high level, under the control of which the fourth thin film transistor M4 is further turned on and a low level input from the first signal end Clkn+1 is further transmitted to the output end Eout through the fourth thin film transistor M4. So that the output end Eout outputs the low level to the light-emitting unit to further initialize the data of the light-emitting unit, and to further remove the light-emitting display data of the previous stage. That is to say, the second initialization sub-stage T12 can increase an initialization time for the light-emitting unit to better remove the light-emitting display data of the previous stage.

In the compensation stage T2, the third signal end Gn inputs a high level, under the control of which the first thin film transistor M1 is turned on; the fourth signal end Gn+1 inputs a high level, under the control of which the second thin film transistor M2 is turned on, and the sixth signal end Eclkn+1 inputs a low level, under the control of which the fifth thin film transistor M5 is turned off and the second node PU is at a low level. The turned on the first thin film transistor M1 and the turned on second thin film transistor M2 make the first node PD at a high level, under the control of which, the fourth thin film transistor M4 is turned on and a high level input from the first signal end Clkn+1 is transmitted to the output end Eout through the fourth thin film transistor M4. So the high level output from the output end Eout is input to the light-emitting unit to control the light-emitting unit to perform data compensation.

In the data write-in stage T3, the third signal end Gn inputs a high level, under the control of which the first thin film transistor M1 is turned on and the first node PD is at a high level; the fourth signal end Gn+1 inputs a low level, under the control of which the second thin film transistor M2 is turned off; and the sixth signal end Eclkn+1 inputs a low level, under the control of which the fifth thin film transistor M5 is turned off and the second node PU is at a low level.

Under the control of the high level of the first node PD, the fourth thin film transistor M4 is turned on and a low level input from the first signal end Clkn+1 is transmitted to the output end Eout through the fourth thin film transistor M4. So the low level output from the output end Eout controls the light-emitting unit to receive light-emitting data.

In the light-emitting stage T4, the third signal end Gn inputs a low level, under the control of which the first thin film transistor M1 is turned off; the fourth signal end Gn+1 inputs a high level, under the control of which the second thin film transistor M2 is turned on and the first node PD is at a high level; and the sixth signal end Eclkn+1 inputs a low level, under the control of which the fifth thin film transistor M5 is turned off and the second node PU is at a low level. Under the control of the high level of the first node PD, the fourth thin film transistor M4 is turned on and a high level input from the first signal end Clkn+1 is transmitted to the output end Eout through the fourth thin film transistor M4. So, the high level output from the output end Eout controls the light-emitting unit to perform light-emitting display based on the received light-emitting data. In this embodiment, a duration of the light emitting stage T4 is twice a duration of the data write-in stage T3. In other embodiments, a duration of the light-emitting stage T4 is the same as a duration of the data-writing stage T3.

In the light-emitting holding stage T5, the third signal end Gn inputs a low level, under the control of which the first thin film transistor M1 is turned off; the fourth signal end Gn+1 inputs a low level, under the control of which the second thin film transistor M2 are turned off; and the sixth signal end Eclkn+1 inputs a high level, under the control of which the fifth thin film transistor M5 is turned on and a high level from the second signal end VGH is input to the second node PU. Under the control of the high level of the second node PU, on one hand, the third thin film transistor M3 is turned on and a low level from the fifth signal end VGL is transmitted to the first node PD through the third thin film transistor M3, under the control of which the fourth thin film transistor M4 is turned off, on the other hand, the sixth thin film transistor M6 is turned on and a high level from the second signal end VGH is input to the output end Eout through the sixth thin film transistor M6. So, the high level output from the output end Eout controls the light-emitting unit to continue to emit light. The first signal end Clkn+1 inputs a low level. In the light-emitting stage T4 and the light-emitting holding stage T5, levels input from the output end Eout are high levels, so the high level of the light-emitting holding stage T5 is switched from the high level of the light-emitting stage T4 without the mutual pulling between a high level and a low level. As such, output stability of the high levels of the output end Eout will be not adversely affected, thereby improving display stability of the light-emitting unit.

It should be noted that, during the light-emitting holding stage T5, the second node PU is at a high level. During the first initialization stage T11 in the next time period, a pull-down circuit for pulling down the second node PU may be arranged on a line of the second node PU, so that the second node PU is at a low level during the first initialization stage T11 in the next time period.

In this embodiment, two thin film transistors (M1 and M2) for controlling the first node PD are arranged in the pull-down control module 100, and two adjacent pulse signals (Gn and Gn+1) are used to control the above two thin film transistors respectively, so that the first node PD is at a high level during both the data write-in stage T3 and the light-emitting stage T4. Therefore, the output results of the output end Eout controlled by a signal of the first signal end Clkn+1 in both the data write-in stage T3 and the light-emitting stage T4 are controlled by the pull-down control module 100 (M1, M2 and M3), so that no switching between the pull-down control module 100 and the pull-up control module 300 (M5) is involved during the data write-in stage T3 and the light-emitting stage T4. Further, the low level of the output end Eout in the data write-in stage T3 can be quickly switched to the high level of that in the light-emitting stage T4, by which the light-emitting unit can emit light in time, thereby improving a light-emitting effect.

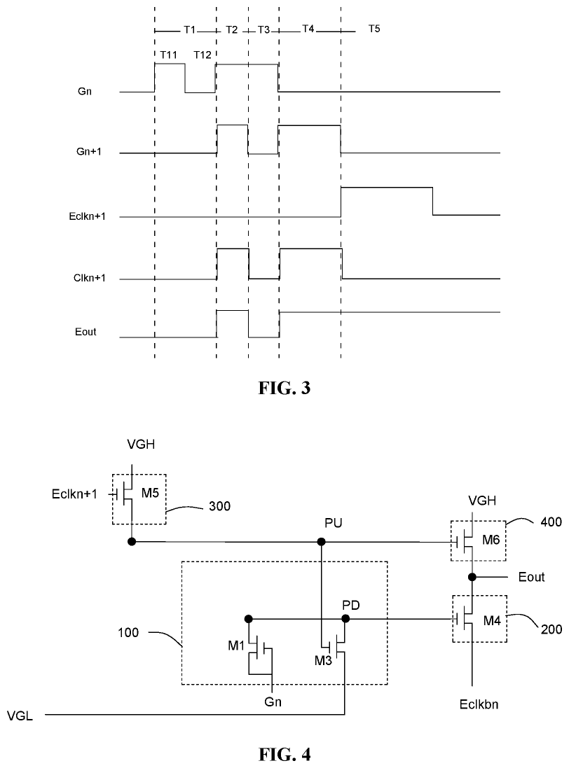

To describe the beneficial effects of the present application, the present application further provides a first comparative embodiment. Referring to FIG. 4 and FIG. 5, in the first comparative embodiment, the data write-in stage T3 and the light-emitting stage T4 are controlled by the pull-down control module 100 and the pull-up control module 300 respectively. The first comparative embodiment differs from the second embodiment in that there is no second thin film transistor M2 and an operation time sequence is different. The working process of the scanning drive circuit is analyzed with reference to FIG. 4 and FIG. 5, and the details are as follows.

In the initialization stage T1, Gn inputs a high level, under the control of which the first node PD is at a high level; Eclkn+1 inputs a low level, under the control of which the fifth thin film transistor M5 is turned off, the second node PU is at a low level, and the sixth thin film transistor M6 is turned off; and Eclkbn inputs a low level. Under the control of the high level of the first node PD, the fourth thin film transistor M4 is turned on, the low level of Eclkbn is input to the output end Eout through the fourth thin film transistor M4, and further to the light-emitting unit. So, the light-emitting unit has been initialized.

In the compensation stage T2, Gn inputs a high level, under the control of which the first node PD is at a high level; Eclkbn inputs a high level; and Eclkn+1 inputs a low level, under the control of which the second node PU is at a low level. Under the control of the high level of the first node PD, the output end Eout outputs a high level to the light-emitting unit, so that the light-emitting unit performs data compensation.

In the data write-in stage T3, Gn inputs a low level; Eclkbn inputs a low level; Eclkn+1 inputs a low level, under the control of which the second node PU is at a low level. The first node PD is held at a high level, and the output end Eout outputs a low level to the light-emitting unit.

In the light-emitting stage T4, Gn inputs a low level; Eclkbn inputs a low level; andEclkn+1 inputs a high level, under the control of which the fifth thin film transistor M5 is turned on and a high level from VGH is input to the second node PU turning on the third thin film transistor M3 because the gate of the third thin film transistor M3 is connected to the second node PU. Then a low level from VGL is transmitted to the first node PD through the third thin film transistor M3 to make a level of the first node PD become a low level. In this process, it takes a certain time for the high level of the second node PU to be transmitted to the gate of the third thin film transistor M3, in other words, it takes a certain time to fully turn on the third thin film transistor M3. Additionally, the gate of the third thin film transistor M3 shunts a part of the high level of the second node PU, so that the high level of the second node PU cannot be pulled up in time, in other words, the high level cannot be pulled up in time to a potential that can turn on the sixth thin film transistor M6. A gate voltage of the sixth thin film transistor M6 needs to be boosted for a certain period of time before a channel between the first electrode and the second electrode (i.e., a source and a drain) is enabled. Once the channel is enabled, the sixth thin film transistor M6 is turned on. If the potential of the sixth thin film transistor M6 cannot be pulled up in time, the sixth thin film transistor M6 cannot be turned on in time, and consequently the high level from VGH cannot be input to the output end Eout through the sixth thin film transistor M6 in time. As a result, the output end Eout cannot input the high level to the light-emitting unit in time, a light-emitting time of the light-emitting unit is delayed, and a light-emitting effect is degraded.

In the first comparative embodiment, because the gate of the third thin film transistor M3 in the pull-down control module 100 is connected to the pull-up control module 300 through the second node PU, a signal switched to to the pull-up control module 300 in the light-emitting stage T4 from the pull-down control module 100 in the data write-in stage T3 is delayed, and light-emitting display of the light-emitting unit is further delayed. However, in the second embodiment of the present application, no switching between the pull-down control module 100 and the pull-up control module 300 (M5) is involved during the data write-in stage T3 and the light-emitting stage T4, and a signal of the pull-up control module 300 (M5) does not interfere with a signal of the pull-down control module 100, so that a low level of the output end Eout in the writing stage T3 can be quickly pulled up to a high level of that in the light-emitting stage T4, and the light-emitting unit can be controlled via the high level to emit light in time, thereby improving a light-emitting effect.

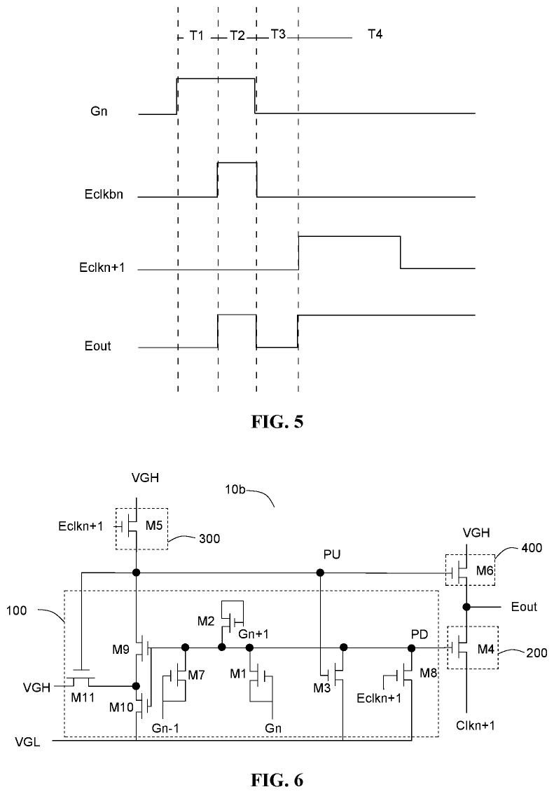

Referring to FIG. 6, a third embodiment of the present invention provides a scanning drive circuit 10b. The third embodiment differs from the second embodiment in that, in the scanning drive circuit 10bthe pull-down control module 100 further includes a seventh thin film transistor M7, in which a gate and a first electrode are connected to a seventh signal end Gn−1 respectively, and a second electrode is connected to the first node PD.

In the initialization stage T1, the seventh signal end Gn−1 inputs a first level; the third signal end Gn and the fourth signal end Gn+1 input a second level respectively; and the first signal end Clkn+1 inputs a low level. Under the control of the first level of the seventh signal end Gn−1, the seventh thin film transistor M7 is turned on and the first level is input to the first node PD. The first thin film transistor M1 and the second thin film transistor M2 are turned off under control by the second level of the third signal end Gn and the second level of the fourth signal end Gn+1 respectively. Under the control of the first level of the first node PD, the low level of the first signal end Clkn+1 is transmitted to the output end

Eout, and the low level from the output end Eout controls the light-emitting unit to be initialized. Compared with the second embodiment, adding the seventh thin film transistor M7 can increase the initialization time. In this embodiment, a time of the initialization controlled by the seventh thin film transistor M7 is before a time of the initialization controlled by the first thin film transistor M1 and the second thin film transistor M2.

In a further embodiment, the pull-down control module 100 further includes an eighth thin film transistor M8, in which a gate is connected to the sixth signal end Eclkn+1, a first electrode is connected to the fifth signal end VGL, and a second electrode is connected to the first node PD. The scanning drive circuit 10b further has a light-emitting holding stage T5 after the light-emitting stage T4.

In the light-emitting stage T4, the sixth signal end Eclkn+1 inputs a second level, under the control of which the eighth thin film transistor M8 is turned off.

In the light-emitting holding stage T5, the sixth signal end Eclkn+1 inputs a first level, under the control of which the eighth thin film transistor M8 is turned on. The fifth signal end VGL inputs a low level, which is transmitted to the first node PD through the eighth thin film transistor M8. Under the control of the low level of the first node PD, the pull-down output module 200 is turned off Compared with the second embodiment, the eighth thin film transistor M8 can quickly pull down a potential of the first node PD in the light-emitting holding stage, so that the fourth thin film transistor M4 is turned off in time, and is successfully switched to the sixth thin film transistor M6, for the sixth thin film transistor M6 to control an output result of the output end Eout.

In a further embodiment, the pull-down control module 100 further includes a ninth thin film transistor M9, in which a gate is connected to the first node PD, a first electrode is connected to the pull-up control module 300, and a second electrode is connected to the fifth signal end VGL.

In a further embodiment, the pull-down control module 100 further includes a tenth thin film transistor M10 and an eleventh thin film transistor M11.

In the tenth thin film transistor M10, a gate is connected to the first node PD, a first electrode is connected to the second electrode of the ninth thin film transistor M9, and a second electrode is connected to the fifth signal end VGL. The second electrode of the ninth thin film transistor M9 is connected to the fifth signal end VGL through the tenth thin film transistor M10.

In the eleventh thin film transistor M11, a gate is connected to the first electrode of the ninth thin film transistor M9, a first electrode is connected to the second signal end VGH, and a second electrode of the eleventh thin film transistor M11 is connected to the first electrode of the tenth thin film transistor M10. The ninth thin film transistor M9 and the tenth thin film transistor M10 can improve stability of the scanning drive circuit.

In a further embodiment, at least one of the first thin film transistor M1, the second thin film transistor M2 and the third thin film transistor M3 is a double-gate thin film transistor, which can improve stability of electrical signals. In other embodiments, at least one or all of the thin film transistors in the scanning drive circuit 10 are double-gate thin film transistors to improve signal stability of the scanning drive circuit 10.

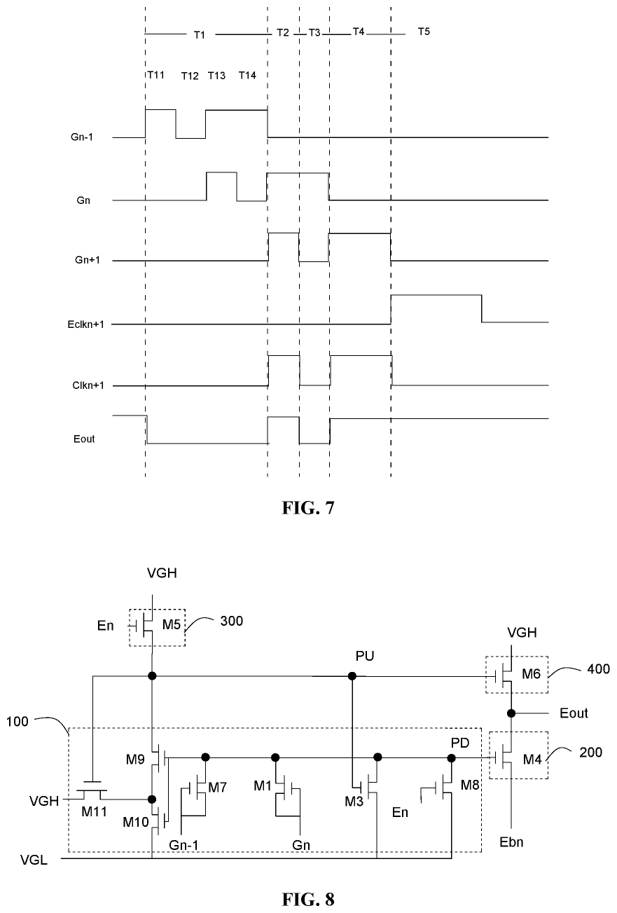

To describe a working process of the third embodiment, refer to FIG. 6 and FIG. 7. FIG. 7 illustrates an operation time sequence of the third embodiment. The details are as follows:

The initialization stage T1 includes a first initialization sub-stage T11, a second initialization sub-stage T12, a third initialization sub-stage T13 and a fourth initialization sub-stage T14. In the following description, device names are omitted and are directly represented by reference signs to simplify the description.

In the first initialization sub-stage T11, Gn−1 is at a high level; Gn, Gn+1, ECLKn+1 and CLKn+1 each are at a low level. In this case, M7 is turned on, and the high level reaches the node PD through M7. Under the control of the high level of the node PD, M4 is turned on, and the low level of CLKn+1 is output from Eout, i.e., Eout outputs a low level at this time. M5, M1, M2 and M8 are turned off respectively; the gates of M9 and M10 are connected to the node PD respectively; and a low level of VGL is transmitted to the node PU through M9 and M10 when M9 and M10 are turned on respectively, which make the node PU pulled down to a low level. That is, in this embodiment, the node PU is pulled down to a low level through M9 and M10, under the control of which M3 and M6 are turned off, and M11 is turned off due to its gate is connected to the node PU.

In the second initialization sub-stage T12, Gn−1 is changed to a low level, and Gn, Gn+1, ECLKn+1, and CLKn+1 are held at a low level respectively. In this case, M7 is turned off; M1, M2, M8 and M3 that are connected to the node PD are turned off; and the gates of M9 and M10 are respectively connected to the node PD. In this case, the node PD is held at a high level for a short period of time, and Eout keeps outputting a low level.

In the third initialization sub-stage T13, Gn−1 and Gn each are at a high level, and Gn+1, ECLKn+1 and CLKn+1 each are at a low level. In this case, M7 and M1 are turned on, then a high level is input to the node PD through M7 and M1. The node PD is still held at a high level, so M4 is turned on, then the low level of CLKn+1 is output from Eout, i.e., Eout outputs a low level.

In the fourth initialization sub-stage T14, Gn−1 is at a high level; and Gn, Gn+1, ECLKn+1 and CLKn+1 each are at a low level. In this case, M7 is turned on, then a high level is input to the node PD through M9. The node PD is still held at a high level, so M4 is turned on, and then the low level of CLKn+1 is output from Eout, i.e., Eout outputs a low level at this time. In this embodiment, the four initialization sub-stages can better remove the light-emitting data retained from the previous stage.

In the compensation stage T2, Gn−1 is at a low level; Gn and Gn+1 each are at a high level; ECLKn+1 is at a low level; and CLKn+1 is at a high level. In this case, M2 and M1 are turned on, and then a high level transmitted by M2 and M1 is transmitted to the node PD. The node PD is still held at a high level, so M4 is turned on, and then the high level of CLKn+1 is output from Eout, i.e., Eout outputs a high level at this time to control the light-emitting unit for compensation. The gates of M9 and M10 are respectively connected to the node PD, so M9 and M10 are respectively turned on, and then the low level of VGL is transmitted to the node PU through M9 and M10. The node PU is held at a low level, and M8, M3, M6, M5 and M11 are turned off respectively.

In the data write-in stage T3, Gn−1 is at a low level; Gn is at a high level, and Gn+1, ECLKn+1 and CLKn+1 each are at a low level. In this case, M1 is turned on, and M1 transmits a high level to the node PD. The node PD is still held at a high level, so M4 is turned on, and then the low level of CLKn+1 is output from Eout, i.e., Eout outputs a low level at this time to control the light-emitting unit to input light-emitting data. The gates of M9 and M10 are respectively connected to the node PD, so M9 and M10 are respectively turned on, and then a low level of VGL is transmitted to the node PU through M9 and M10, so that the node PU is pulled down to a low level, and M8, M3, M6, M2, M5 and M11 are turned off respectively.

In the light-emitting stage T4, Gn−1 and Gn each are at a low level;

Gn+1 is at a high level; ECLKn+1 is at a low level; and CLKn+1 is at a high level. In this case, M2 is turned on, which transmits a high level to the node PD. The node PD is still held at a high level, so M4 is turned on, and then the high level of CLKn+1 is output from Eout, i.e., Eout outputs a high level to control the light-emitting unit to emit light based on the received light-emitting data. The gates of M9 and M10 are respectively connected to the node PD, so M9 and M10 are respectively turned on, and then a low level of VGL is transmitted to the node PU through M9 and M10, so that the node PU is held at a low level, and M8, M3, M6, M1, M5 and M11 are turned off. That is, in the light-emitting stage T4 and the data write-in stage T3, the pull-down control module 100 controls the first node PD to be at a high level, without involving a process of signal switching between the pull-up control module 300 and the pull-down control module 100, so that output results of the output end Eout are all provided by the pull-down output module 200. This prevents a light-emitting display effect from being affected when the output end Eout cannot output a high level in time during switching between the light-emitting stage T4 and the data write-in stage T3.

In the light-emitting holding stage T5, Gn−1, Gn and Gn+1 each are at a low level; ECLKn+1 is at a high level, and CLKn+1 is at a low level. In this case, ECLKn+1 is at a high level, so M5 is turned on, then a high level of VGH is input to the node PU, then M6 is turned on, and then the high level of VGH is output from Eout through M6, i.e., Eout outputs a high level to keep the light-emitting unit emitting light. The node PU is at a high level, so M3 is turned on, then M8 is turned on, then a low level of VGL is input to the node PD through M3 and M8. The node PD is at a low level, so M7, M2, M1, M4, M9 and M10 are turned off Due to the gate of M11 is connected to the node PU, M11 is turned on, and a high level of VGH is transmitted to the second electrode of M9 and the first electrode of M10 through M11, and a potential difference between the second electrode and the gate of M9 is increased, and a potential difference between the first electrode and the gate of M10 is also increased, and M9 and M10 are further turned off That is, in this embodiment, M9, M10 and M11 work together to prevent a low-level signal of VGL from pulling down the level of the second node PU, so as to improve light-emitting stability. In the light-emitting holding stage T5 and the light-emitting stage T4, levels input from the output end Eout are all high levels, switching is performed between high levels, and there is no mutual pulling between a low level and a high level. Such implementation does not affect output stability of the high levels of the output end Eout, and does not affect light-emitting display stability of the light-emitting unit.

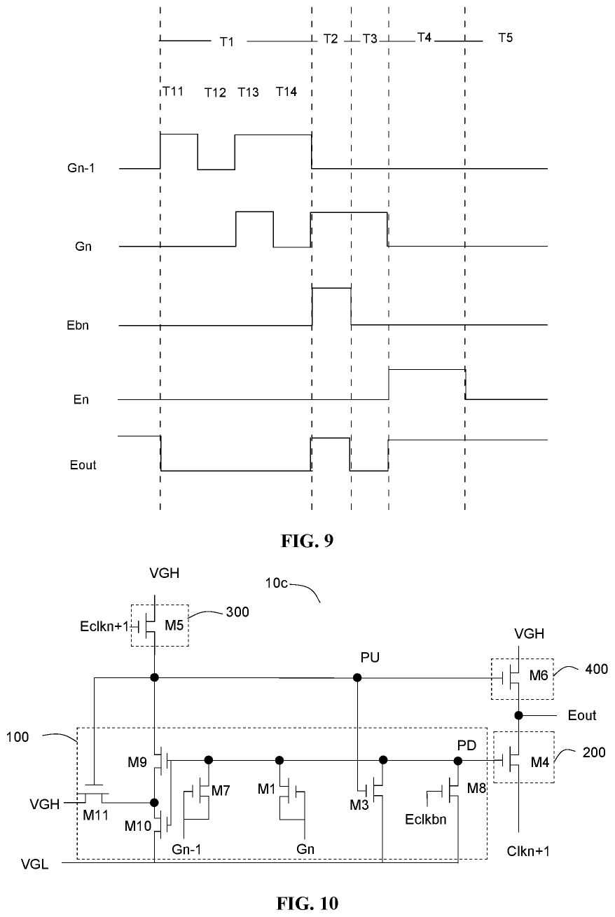

To compare and illustrate the beneficial effects of the third embodiment, the present application further provides a second comparative embodiment (as shown in FIG. 8). The second comparative embodiment differs from the third embodiment in that no second thin film transistor M2 is provided in the second comparative embodiment, and an operation time sequence differs from that of the second embodiment. Details are shown in FIG. 9. The operation of the second comparative embodiment will be described below with reference to FIG. 8 and FIG. 9, where the initialization stage Ti and the compensation stage T2 are similar to those of the third embodiment, which will not be repeated here.

In the data write-in stage T3, Gn−1 is at a low level; Gn is at a high level; and En and Ebn each are at a low level. In this case, the node PD is at a high level, the node PU is at a low level, Eout outputs a low level.

In the light-emitting stage T4, Gn−1, Gn and Ebn each are at a low level; and En is at a high level. M8 is turned on; the node PD is at a low level; and M4 is turned off M5 is turned on, the node PU is at a high level, M6 is turned on, and Eout outputs a high level. In this process, the node PD is at a high level during the data write-in stage T3, and this high level does not disappear immediately and is delayed, so that M9 and M10 are still turned on during this time delay period. A part of a high level of VGH is transmitted to M9 and M10 through M5, and as a result, the node PU cannot be pulled up in time. In addition, the node PU is connected to the gate of M3. After a part of a potential of the node PU is shunted by the gates of M9 and M10, the pulled-up potential of PU is reduced, and consequently, M3 cannot be effectively turned on in a short time, and a time for pulling down a potential of the node PD is prolonged. During the switching process, a time for pulling up the node PU to a high level is prolonged, a time for pulling down the node PD to a low level is prolonged, and a time for Eout to rise from a low level to a high level is prolonged. In this case, a potential of Eout is used to control a light-emitting element to emit light, so that a time for starting to emit light is delayed.

Referring to FIG. 10, a fourth embodiment of the present invention provides a scanning drive circuit 10c. In the scanning drive circuit 10c, the pull-down control module includes a first thin film transistor M1, a third thin film transistor M3 and an eighth thin film transistor M8.

A first electrode of the first thin film transistor M1 is connected to the first node PD, a gate and a second electrode of the first thin film transistor M1 are connected to a third signal end Gn. A gate of the third thin film transistor M3 is connected to the pull-up control module 300, a first electrode of the third thin film transistor M3 is connected to a fifth signal end VGL, and a second electrode of the third thin film transistor M3 is connected to the first node PD. A gate of the eighth thin film transistor M8 is connected to an eighth signal end Eclkbn, a first electrode of the eighth thin film transistor M8 is connected to the fifth signal end VGL, and a second electrode of the eighth thin film transistor M8 is connected to the first node PD. The light-emitting stage T4 includes a first light-emitting sub-stage T41 and a second light-emitting sub-stage T42 after the first light-emitting sub-stage T41.

In the data write-in stage T3, a third signal end Gn inputs a first level, under the control of which the first thin film transistor M1 is turned on and the first level is input to the first node PD through the first thin film transistor M1. So the first node PD is at the first level, under the control of which the pull-down output module 200 is transmitted a low level of the first signal end Clkn+1 to the output end Eout.

In the first light-emitting sub-stage T41, the third signal end Gn inputs a second level and the eighth signal end Eclkbn inputs a second level. So, the first thin film transistor M1 is turned off under control by the second level, the eighth thin film transistor M8 is turned off under control by the second level, the first node PD is held at the first level, the first level controls the pull-down output module 200 to transmit a high level of the first signal end Clkn+1 to the output end Eout, and the high level output from the output end Eout is used to control the light-emitting unit to emit light.

In the second light-emitting sub-stage T42, the third signal end Gn inputs a second level; and the eighth signal end Eclkbn inputs a first level. So the first thin film transistor M1 is turned off under control by the second level, the eighth thin film transistor M8 is turned on under control by the first level, a low level of the fifth signal end VGL is input to the first node PD through the eighth thin film transistor M8, the first node PD is at a low level, the low level controls the pull-down output module 200 to be turned off, and the output end Eout holds an output of a high level and controls, via the high level, the light-emitting unit to emit light.

In this embodiment, in the second light-emitting sub-stage T42 of the light-emitting stage T4, a potential of the first node PD is pulled down in advance. If the first node PD is still held at a high level in the second light-emitting sub-stage T42, the high level of the first node PD adversely affects a signal of the pull-up control module 300 during switching between the pull-down control module 100 and the pull-up control module 300 in the light-emitting holding stage T5. Therefore, in this embodiment, in the second light-emitting sub-stage T42 of the light-emitting stage T4, the potential of the first node PD is pulled down in advance to prevent the high level of the first node PD from pulling the signal of the pull-up control module 300 when the light-emitting holding stage T5 arrives.

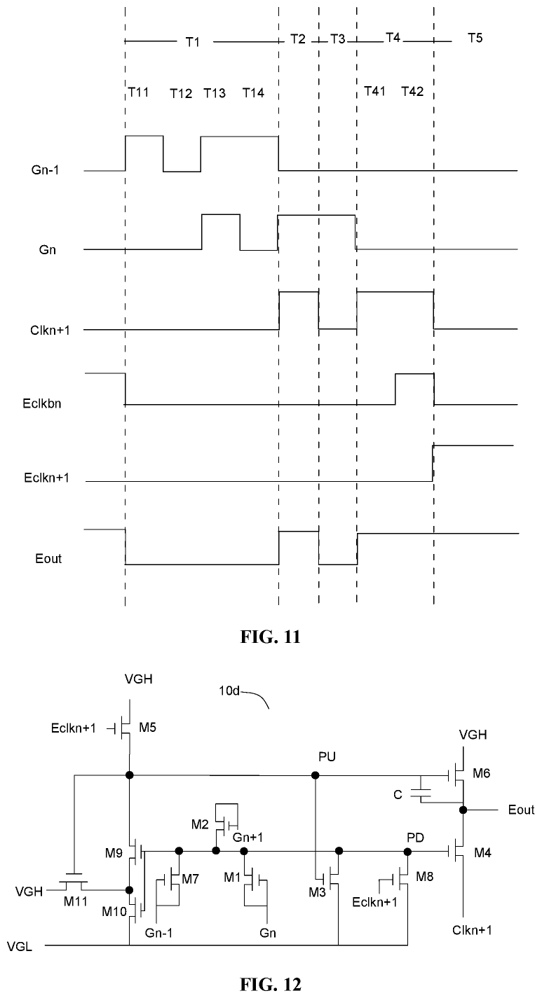

Specifically, referring to FIG. 10 and FIG. 11, the fourth embodiment differs from the third embodiment in that there is no second thin film transistor M2 in FIG. 10, and the gate of the eighth thin film transistor M8 is connected to the eighth signal end Eclkbn. A working process of the fourth embodiment is described below, where the initialization stage Ti is the same as that of the third embodiment, and will not be repeated here.

In the compensation stage T2, Gn−1 is at a low level; Gn is at a high level; Clkn+1 is at a high level; and Eclkbn and Eclkn+1 each are at a low level. M1 is turned on; the node PD is at a high level; M4 is turned on; M5 is turned off; the node PU is at a low level; and M6 is turned off The high level of Clkn+1 is transmitted to the output end Eout through M4, and is input to the light-emitting unit through the output end Eout to compensate for the light-emitting unit.

In the data write-in stage T3, Gn−1 is at a low level; Gn is at a high level; and Clkn+1, Eclkbn and Eclkn+1 each are at a low level. M1 is turned on; the node PD is at a high level; M4 is turned on; M5 is turned off; the node PU is a low level; and M6 is turned off The low level of Clkn+1 is transmitted to the output end Eout through M4, and is input to the light-emitting unit through the output end Eout to control the light-emitting unit to receive light-emitting data.

The light-emitting stage T4 includes the first light-emitting sub-stage T41 and the second light-emitting sub-stage T42 after the first light-emitting sub-stage T41.

In the first light-emitting sub-stage T41, Gn−1 is at a low level; Gn is at a low level; Clkn+1 is at a high level; Eclkbn is at a low level; and Eclkn+1 is at a low level. M7. M1 and M8 are turned off; the node PD is held at a high level; M5 is turned off; the node PU is at a low level; M3 and M6 are turned off; and the high level of the node PD in the data write-in stage T3 is not pulled down. Therefore, in the first light-emitting sub-stage T41, the node PD is held at a high level, M4 is turned on, and the high level of Clkn+1 is transmitted to the output end Eout through M4 and is input to the light-emitting unit from the output end Eout to control the light-emitting unit to emit light.

In the second light-emitting sub-stage T42, Gn−1 is at a low level; Gn is at a low level; Clkn+1 is at a high level; Eclkbn is at a high level; and Eclkn+1 is at a low level. M7 and M1 are turned off; M5 is turned off; the node PU is at a low level; M3 is turned off; M8 is turned on; the node PD is at a low level; M9, M10, M4 are turned off; the node PU is still at a low level; and M6 is turned off In this case, the output end Eout has no signal input, and a high level signal in the previous stage (T41) is held for the output end Eout, i.e., the high level of the output end Eout is input to the light-emitting unit to control the light-emitting unit to emit light. The first light-emitting sub-stage T41 and the second light-emitting sub-stage T42 both are controlled by the pull-down control module 100, and a signal of the output end EOUT is output by the pull-down output module 200, without involving signal pulling between the pull-down control module 100 and the pull-up control module 300, thereby ensuring that the signal output by the output end Eout controls the light-emitting unit to emit light in time.

In the light-emitting holding stage T5, Gn−1, Gn, Clkn+1 and Eclkbn each are at a low level; and Eclkn+1 is at a high level. M5 is turned on; the node PU is at a high level; and M6 is turned on. Because the node PU is already at a low level, and M9 and M10 have already been turned off in advance in the second light-emitting sub-stage T42, the high level of the node PU is not pulled, and a time for pulling up the high level of the node PU is not affected at this stage. Therefore, a high level of VGH and a high level of the node PU can be output to the output end Eout through M6, so that the light-emitting unit can be controlled to emit light in time.

Referring to FIG. 12, a fifth embodiment of the present invention provides a scanning drive circuit 10d. The fifth embodiment differs from the third embodiment in that the scanning drive circuit 10d further includes a capacitor C, where one end of the capacitor C is connected to the second node PU, and the other end thereof is connected to the output end Eout. When the output end Eout outputs a high level during the light-emitting stage T4, the capacitor C can be charged by the high level. In this case, the capacitor C can store a certain high level. During the light-emitting holding stage T5, the second node PU is pulled up, the capacitor C with a high level can assist in pulling up the second node PU, so that the second node PU is pulled up quickly, and then the pull-up output module (M6) can be controlled to be turned on in time. As such, a high level of the second signal end VGH can be input to the output end Eout in time.

It should be noted that in the present application, the gate and the second electrode of the first thin film transistor M1 are connected to the same signal end Gn, which can save traces. In other embodiments, the gate and the second electrode of the first thin film transistor M1 can be connected to different signal ends respectively, and functions thereof can be kept the same as those of the present application. Similarly, the gate and the first electrode of the second thin film transistor M2 may also be connected to different signal ends respectively, and functions thereof can be kept the same as those of the present application. The gate and the first electrode of the seventh thin film transistor M7 may also be connected to different signal ends respectively, and functions thereof can be kept the same as those of the present application. It should be noted that when the gate and second electrode of the first thin film transistor M1, the gate and the first electrode of the second thin film transistor M2, and the gate and first electrode of the seventh thin film transistor M7 are connected to different signal ends respectively, the first thin film transistor M1, the second thin film transistor M2 and the seventh thin film transistor M7 may be N-type thin film transistors or P-type thin film transistors, provided that implemented functions are the same as those of the present application.

It should also be noted that circuits with the pull-down control module 100, the pull-down output module 200, the pull-up control module 300 and the pull-up output module 400 are not limited to those described in the foregoing embodiments, and other circuits that can achieve the same functions as the foregoing embodiments are also available.

Referring to FIG. 13, an embodiment of the present invention further provides a display panel 20. The display panel 20 includes a light-emitting unit 40 and the scanning drive circuit 10 according to any one of the above embodiments, where the scanning drive circuit 10 controls the light-emitting unit 40 to emit light. The display panel 20 is provided with the scanning drive circuit 10 that can control the light-emitting unit 40 to emit light for display in time. Such implementation can improve a light-emitting display effect of the display panel 20.

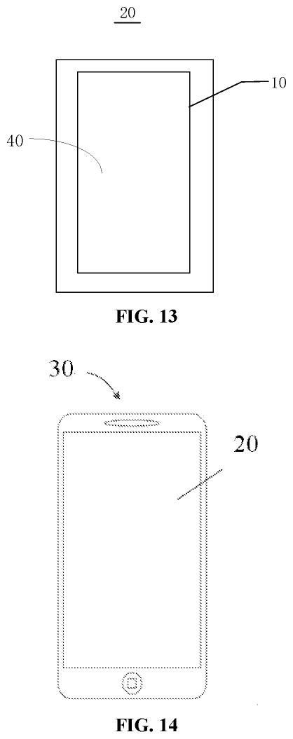

Referring to FIG. 14, in an embodiment, an electronic apparatus 30 is further included, and the electronic apparatus 30 includes the display panel 20 described above or the scanning drive circuit 10 according to any one of the above embodiments. The electronic apparatus 30 may be, but is not limited to, an e-book, a smartphone (such as an Android phone, an iOS phone and a Windows phone), a tablet computer, a flexible handheld computer, a flexible notebook computer, a mobile Internet device (MID) or a wearable device.

The above-mentioned embodiments express only several implementations of the present invention, and the description thereof is relatively specific and detailed, but it should not be understood as a limitation to the patent scope of the present invention. It should be noted that a person of ordinary skill in the art may further make several modifications and improvements without departing from the concept of the present invention. These modifications and improvements shall fall within the protection scope of the present invention. Therefore, the patent protection scope of the present invention should be subject to the appended claims

Claims what is claimed is:

1. A scanning drive circuit, comprising a pull-down control module, a pull-down output module, a pull-up control module and an output end, wherein the pull-down control module is connected to the pull-up control module, a first node is arranged between the pull-down control module and the pull-down output module, the pull-down control module and the pull-down output module are electrically connected to the first node, respectively, the output end is configured to be connected to a light-emitting unit, one end of the pull-down output module is connected to a first signal end, and the other end of the pull-down output module is connected to the output end; and the scanning drive circuit has a data write-in stage and a light-emitting stage, and the light-emitting stage is after the data write-in stage;
in the data write-in stage, the first signal end inputs a low level, the pull-down control module controls the first node to be at a first level, and the first level of the first node controls the pull-down output module to transmit the low level of the first signal end to the output end; and
in the light-emitting stage, the first signal end inputs a high level, the pull-down control module controls the first node to be at the first level, the first level of the first node controls the pull-down output module to transmit the high level of the first signal end to the output end, and the high level output from the output end is used to control the light-emitting unit to emit light.

2. The scanning drive circuit according to claim 1, wherein the scanning drive circuit further has an initialization stage and a compensation stage, and the compensation stage is after the initialization stage and between the initialization stage and the data write-in stage;
in the initialization stage, the first signal end inputs a low level, the pull-down control module controls the first node to be at the first level, and the first level of the first node controls the pull-down output module to transmit the low level to the output end; and
in the compensation stage, the first signal end inputs a high level, the pull-down control module controls the first node to be at the first level, and the first level of the first node controls the pull-down output module to transmit the high level to the output end.

3. The scanning drive circuit according to claim 1, further comprising a pull-up output module, wherein a second node is arranged between the pull-up control module and the pull-up output module, both the pull-up control module and the pull-up output module are electrically connected to the second node, one end of the pull-up output module is connected to a second signal end, and the other end of the pull-up output module is connected to the output end; and the scanning drive circuit further has a light-emitting holding stage, and the light-emitting holding stage is after the light-emitting stage; and
in the light-emitting holding stage, the second signal end inputs a high level, the pull-up control module controls the second node to be at a first level, the first level of the second node controls the pull-up output module to transmit the high level to the output end, and the high level output from the output end controls the light-emitting unit to emit light.

4. The scanning drive circuit according to claim 1, wherein the pull-down control module comprises a first thin film transistor, a second thin film transistor and a third thin film transistor;
a first electrode of the first thin film transistor is connected to the first node, a gate and a second electrode of the first thin film transistor are respectively connected to a third signal end, a gate and a first electrode of the second thin film transistor are respectively connected to a fourth signal end, a second electrode of the second thin film transistor is connected to the first node, a gate of the third thin film transistor is connected to the pull-up control module, a first electrode of the third thin film transistor is connected to a fifth signal end, and a second electrode of the third thin film transistor is connected to the first node;
in the data write-in stage, the third signal end inputs a first level, the fourth signal end inputs a second level, the first thin film transistor is turned on under control by the first level of the third signal end, the first level is input to the first node through the first thin film transistor, so that the first node is at the first level, the second thin film transistor is turned off under control by the second level of the fourth signal end, and the first level of the first node controls the pull-down output module to transmit the low level of the first signal end to the output end; and
in the light-emitting stage, the third signal end inputs a second level, the fourth signal end inputs a first level, the first thin film transistor is turned off under control by the second level of the third signal end, the second thin film transistor is turned on under control by the first level of the fourth signal end, the first level of the fourth signal end is input to the first node through the second thin film transistor, so that the first node is at the first level, the first level of the first node controls the pull-down output module to transmit the high level of the first signal end to the output end, and the high level output from the output end is used to control the light-emitting unit to emit light.

5. The scanning drive circuit according to claim 4, wherein the pull-down output module comprises a fourth thin film transistor, a gate of the fourth thin film transistor is connected to the first node, a first electrode of the fourth thin film transistor is connected to the first signal end, and a second electrode of the four thin film transistor is connected to the output end;
in the data write-in stage, the first level of the first node controls the third thin film transistor to be turned on, and the low level of the first signal end is input to the output end through the third thin film transistor; and
in the light-emitting stage, the first level of the first node controls the third thin film transistor to be turned on, the high level of the first signal end is input to the output end through the third thin film transistor, and the high level output from the output end is used to control the light-emitting unit to emit light.

6. The scanning drive circuit according to claim 3, wherein the pull-up control module comprises a fifth thin film transistor, a gate of the fifth thin film transistor is connected to a sixth signal end, a first electrode of the fifth thin film transistor is connected to the second node, and a second electrode of the fifth thin film transistor is connected to the second signal end; and
in the light-emitting holding stage, the sixth signal end inputs a first level, the fifth thin film transistor is turned on, the high level input from the second signal end is input to the second node through the fifth thin film transistor, the high level of the second node controls the pull-up output module to transmit the high level of the second signal end to the output end, and the high level output from the output end controls the light-emitting unit to emit light.

7. The scanning drive circuit according to claim 6, wherein the pull-up output module comprises a sixth thin film transistor, a gate of the sixth thin film transistor is connected to the second node, a first electrode of the sixth thin film transistor is connected to the output end, and a second electrode of the sixth thin film transistor is connected to the second signal end; and
in the light-emitting holding stage, the second signal end inputs the high level, the high level of the second node controls the sixth thin film transistor to be turned on, the high level of the second signal end is input to the output end through the sixth thin film transistor, and the high level output from the output end controls the light-emitting unit to emit light.

8. The scanning drive circuit according to claim 4, wherein the pull-down control module further comprises a seventh thin film transistor, a gate and a first electrode of the seventh thin film transistor are connected to a seventh signal end, and a second electrode of the seventh thin film transistor is connected to the first node; and
in the initialization stage, the seventh signal end inputs a first level, the third signal end and the fourth signal end input a second level, the first signal end inputs a low level, the seventh thin film transistor is turned on under control by the first level of the seventh signal end and inputs the first level to the first node, the first thin film transistor and the second thin film transistor are turned off under control by the second level of the third signal end and the second level of the fourth signal end respectively, the first level of the first node controls the low level of the first signal end to be transmitted to the output end, and the low level output from the output end controls the light-emitting unit to be initialized.

9. The scanning drive circuit according to claim 4, wherein the pull-down control module further comprises an eighth thin film transistor, a gate of the eighth thin film transistor is connected to a sixth signal end, a first electrode of the eighth thin film transistor is connected to the fifth signal end, and a second electrode of the eighth thin film transistor is connected to the first node; and the scanning drive circuit further has a light-emitting holding stage, and the light-emitting holding stage is after the light-emitting stage;
in the light-emitting stage, the sixth signal end inputs a second level, and the eighth thin film transistor is turned off under control by the second level of the sixth signal end; and
in the light-emitting holding stage, the sixth signal end inputs a first level, the fifth signal end inputs a low level, the eighth thin film transistor is turned on under control by the first level of the sixth signal end, the low level of the fifth signal end is transmitted to the first node through the eighth thin film transistor, and the low level of the first node controls the pull-down output module to be turned off.

10. The scanning drive circuit according to claim 4, wherein the pull-down control module further comprises a ninth thin film transistor, a gate of the ninth thin film transistor is connected to the first node, a first electrode of the ninth thin film transistor is connected to the pull-up control module, and a second electrode of the ninth thin film transistor is connected to the fifth signal end.

11. The scanning drive circuit according to claim 10, wherein the pull-down control module further comprises a tenth thin film transistor and an eleventh thin film transistor;
a gate of the tenth thin film transistor is connected to the first node, a first electrode of the tenth thin film transistor is connected to the second electrode of the ninth thin film transistor, a second electrode of the tenth thin film transistor is connected to the fifth signal end, and a second electrode of the ninth thin film transistor is connected to the fifth signal end through the tenth thin film transistor; and
a gate of the eleventh thin film transistor is connected to the first electrode of the ninth thin film transistor, a first electrode of the eleventh thin film transistor is connected to the second signal end, and a second electrode of the eleventh thin film transistor is connected to the first electrode of the tenth thin film transistor.

12. The scanning drive circuit according to claim 4, wherein at least one of the first thin film transistor, the second thin film transistor and the third thin film transistor is a double-gate thin film transistor.

13. The scanning drive circuit according to claim 1, wherein the pull-down control module comprises a first thin film transistor, a third thin film transistor and an eighth thin film transistor;
a first electrode of the first thin film transistor is connected to the first node, a gate and a second electrode of the first thin film transistor are connected to a third signal end, a gate of the third thin film transistor is connected to the pull-up control module, a first electrode of the third thin film transistor is connected to a fifth signal end, a second electrode of the third thin film transistor is connected to the first node, a gate of the eighth thin film transistor is connected to an eighth signal end, a first electrode of the eighth thin film transistor is connected to the fifth signal end, and a second electrode of the eighth thin film transistor is connected to the first node; and the light-emitting stage comprises a first light-emitting sub-stage and a second light-emitting sub-stage, and the second light-emitting sub-stage is after the first light-emitting sub-stage;
in the data write-in stage, the third signal end inputs a first level, the first thin film transistor is turned on under control by the first level, the first level is input to the first node through the first thin film transistor, so that the first node is at the first level, and the first level of the first node controls the pull-down output module to transmit the low level of the first signal end to the output end;
in the first light-emitting sub-stage, the third signal end inputs a second level, the eighth signal end inputs a second level, the first thin film transistor is turned off under control by the second level, the eighth thin film transistor is turned off under control by the second level, the first node is held at the first level, the first level of the first node controls the pull-down output module to transmit the high level of the first signal end to the output end, and the high level output from the output end is used to control the light-emitting unit to emit light; and
in the second light-emitting sub-stage, the third signal end inputs a second level, the eighth signal end inputs a first level, the first thin film transistor is turned off under control by the second level, the eighth thin film transistor is turned on under control by the first level, the low level of the fifth signal end is input to the first node through the eighth thin film transistor, the first node is at a low level, the low level of the first node controls the pull-down output module to be turned off, and the output end holds an output of the high level and controls, via the high level, the light-emitting unit to emit light.

14. A display panel, comprising a light-emitting unit and a scanning drive circuit configured to control the light-emitting unit to emit light, wherein the scanning drive circuit comprises a pull-down control module, a pull-down output module, a pull-up control module and an output end, wherein the pull-down control module is connected to the pull-up control module, a first node is arranged between the pull-down control module and the pull-down output module, the pull-down control module and the pull-down output module are electrically connected to the first node, respectively, the output end is configured to be connected to a light-emitting unit, one end of the pull-down output module is connected to a first signal end, and the other end of the pull-down output module is connected to the output end; and the scanning drive circuit has a data write-in stage and a light-emitting stage, and the light-emitting stage is after the data write-in stage;
in the data write-in stage, the first signal end inputs a low level, the pull-down control module controls the first node to be at a first level, and the first level of the first node controls the pull-down output module to transmit the low level of the first signal end to the output end; and
in the light-emitting stage, the first signal end inputs a high level, the pull-down control module controls the first node to be at the first level, the first level of the first node controls the pull-down output module to transmit the high level of the first signal end to the output end, and the high level output from the output end is used to control the light-emitting unit to emit light.

15. The display panel according to claim 14, wherein the scanning drive circuit further has an initialization stage and a compensation stage, and the compensation stage is after the initialization stage and between the initialization stage and the data write-in stage;
in the initialization stage, the first signal end inputs a low level, the pull-down control module controls the first node to be at the first level, and the first level of the first node controls the pull-down output module to transmit the low level to the output end; and
in the compensation stage, the first signal end inputs a high level, the pull-down control module controls the first node to be at the first level, and the first level of the first node controls the pull-down output module to transmit the high level to the output end.

16. The display panel according to claim 14, wherein the scanning drive circuit further comprises a pull-up output module, wherein a second node is arranged between the pull-up control module and the pull-up output module, both the pull-up control module and the pull-up output module are electrically connected to the second node, one end of the pull-up output module is connected to a second signal end, and the other end of the pull-up output module is connected to the output end; and the scanning drive circuit further has a light-emitting holding stage, and the light-emitting holding stage is after the light-emitting stage; and
in the light-emitting holding stage, the second signal end inputs a high level, the pull-up control module controls the second node to be at a first level, the first level of the second node controls the pull-up output module to transmit the high level to the output end, and the high level output from the output end controls the light-emitting unit to emit light.

17. The display panel according to claim 14, wherein the pull-down control module comprises a first thin film transistor, a second thin film transistor and a third thin film transistor;
a first electrode of the first thin film transistor is connected to the first node, a gate and a second electrode of the first thin film transistor are respectively connected to a third signal end, a gate and a first electrode of the second thin film transistor are respectively connected to a fourth signal end, a second electrode of the second thin film transistor is connected to the first node, a gate of the third thin film transistor is connected to the pull-up control module, a first electrode of the third thin film transistor is connected to a fifth signal end, and a second electrode of the third thin film transistor is connected to the first node;
in the data write-in stage, the third signal end inputs a first level, the fourth signal end inputs a second level, the first thin film transistor is turned on under control by the first level of the third signal end, the first level is input to the first node through the first thin film transistor, so that the first node is at the first level, the second thin film transistor is turned off under control by the second level of the fourth signal end, and the first level of the first node controls the pull-down output module to transmit the low level of the first signal end to the output end; and
in the light-emitting stage, the third signal end inputs a second level, the fourth signal end inputs a first level, the first thin film transistor is turned off under control by the second level of the third signal end, the second thin film transistor is turned on under control by the first level of the fourth signal end, the first level of the fourth signal end is input to the first node through the second thin film transistor, so that the first node is at the first level, the first level of the first node controls the pull-down output module to transmit the high level of the first signal end to the output end, and the high level output from the output end is used to control the light-emitting unit to emit light.

18. The display panel according to claim 17, wherein the pull-down output module comprises a fourth thin film transistor, a gate of the fourth thin film transistor is connected to the first node, a first electrode of the fourth thin film transistor is connected to the first signal end, and a second electrode of the four thin film transistor is connected to the output end;
in the data write-in stage, the first level of the first node controls the third thin film transistor to be turned on, and the low level of the first signal end is input to the output end through the third thin film transistor; and
in the light-emitting stage, the first level of the first node controls the third thin film transistor to be turned on, the high level of the first signal end is input to the output end through the third thin film transistor, and the high level output from the output end is used to control the light-emitting unit to emit light.

19. The display panel according to claim 16, wherein the pull-up control module comprises a fifth thin film transistor, a gate of the fifth thin film transistor is connected to a sixth signal end, a first electrode of the fifth thin film transistor is connected to the second node, and a second electrode of the fifth thin film transistor is connected to the second signal end; and
in the light-emitting holding stage, the sixth signal end inputs a first level, the fifth thin film transistor is turned on, the high level input from the second signal end is input to the second node through the fifth thin film transistor, the high level of the second node controls the pull-up output module to transmit the high level of the second signal end to the output end, and the high level output from the output end controls the light-emitting unit to emit light.

20. The display panel according to claim 19, wherein the pull-up output module comprises a sixth thin film transistor, a gate of the sixth thin film transistor is connected to the second node, a first electrode of the sixth thin film transistor is connected to the output end, and a second electrode of the sixth thin film transistor is connected to the second signal end; and
in the light-emitting holding stage, the second signal end inputs the high level, the high level of the second node controls the sixth thin film transistor to be turned on, the high level of the second signal end is input to the output end through the sixth thin film transistor, and the high level output from the output end controls the light-emitting unit to emit light.
